(19) United States
(12) Patent Application Publication
(10) Pub. No.: US 2024/0050990 A1
(43) Pub. Date: Feb. 15, 2024

(54) APPARATUS FOR TREATING SUBSTRATE AND METHOD FOR TREATING A SUBSTRATE

(71) Applicant: SEMES CO., LTD., Cheonan-si (KR)

(72) Inventors: Do Hyung Kim, Seocheon-gun (KR); Dae Hun Kim, Pyeongtaek-si (KR); Young Jin Kim, Cheonan-si (KR); Tae Ho Kang, Suwon-si (KR); Jun Gwon Lee, Ulsan (KR); Young Joon Han, Cheonan-si (KR); Eun Hyeok Choi, Cheonan-si (KR)

(73) Assignee: SEMES CO., LTD., Cheonan-si (KR)

(21) Appl. No.: 18/169,630

(22) Filed: Feb. 15, 2023

(30) Foreign Application Priority Data
Aug. 10, 2022 (KR) 10-2022-0099643

(51) Int. Cl. B08B 1/00; H01L 21/67; B08B 3/02; A46B 9/00; A46B 9/02; A46D 1/00

(52) U.S. Cl. CPC B08B 1/002; H01L 21/67046; B08B 3/02; A46B 9/005; A46B 9/02; A46D 1/0207; A46B 2200/3073

(57) ABSTRACT

The inventive concept provides a substrate treating apparatus. The substrate treating apparatus includes a housing having a treating space; a support unit configured to support a substrate in the treating space; and a brush unit configured to clean the substrate supported on the support unit, and wherein the brush unit includes: a body having a circular-shaped cross-section; and a plurality of contact pads protruding from the body and defining a plurality of groove portions for discharging foreign substances dropped from a substrate, each groove portion defined between adjacent contact pads, and wherein a width of the groove portion near a center of the body is different from a width of the groove portion near an edge of the body.

### CROSS-REFERENCE TO RELATED APPLICATIONS

A claim for priority under 35 U.S.C. § 119 is made to Korean Patent Application No. 10-2022-0099643 filed on Aug. 10, 2022, in the Korean Intellectual Property Office, the entire contents of which are hereby incorporated by reference.

### BACKGROUND

Embodiments of the inventive concept described herein relate to a substrate treating apparatus and method, more specifically, a substrate treating apparatus and method for cleaning a substrate.

A semiconductor process includes various processes of cleaning foreign substances such as particles, byproducts, etc. and a thin film from a substrate. These processes include cleaning a main surface (pattern surface) of a substrate on which various patterns are formed, and a back side surface (non-pattern surface) of the substrate. In general, the main surface cleaning process is performed by supplying a cleaning liquid to the main surface of the substrate with the main surface facing upward. The back side surface cleaning process is performed by rubbing the back side surface of the substrate with a brush while supplying a liquid to the back side surface of the substrate with the back side surface facing upward.

In order to easily remove foreign substances attached to the back side surface of the substrate, a certain force is must be applied to the substrate when the brush rubs the back side surface of the substrate. However, such the certain force applied for easy removal of foreign substances may damage the substrate e.g., scratches may be generated on the back side surface of the substrate.

The foreign substances separated from the back side surface of the substrate by the brush may be mixed with a liquid supplied to the back side surface of the substrate to generate a contaminated liquid. Since the brush should be contact with the back side surface of the substrate for removing the foreign substances, the contaminated liquid is easily trapped between the brush and the back side surface of substrate. That is, the contaminated liquid is difficult to be discharged to the outside of the brush. While the brush moves on the back side surface of the substrate for cleaning the substrate, the contaminated liquid trapped between the brush and the substrate may contaminate the back side surface of the substrate.

### SUMMARY

Embodiments of the inventive concept provide a substrate treating apparatus and a substrate treating method for increasing a cleaning efficiency of a substrate.

Embodiments of the inventive concept provide a substrate treating apparatus and a substrate treating method for easily discharging a contaminated chemical to an outside of a pad, when cleaning a substrate using the pad.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a housing having a treating space; a support unit configured to support a substrate in the treating space; and a brush unit configured to clean the substrate supported on the support unit, and wherein the brush unit includes: a body having a circular-shaped cross-section; and a plurality of contact pads protruding from the body and defining a plurality of groove portions for discharging foreign substances dropped from a substrate, each groove portion defined between adjacent contact pads, and wherein a width of the groove portion near a center of the body is different from a width of the groove portion near an edge of the body.

In an embodiment, the plurality of contact pads are disposed along a circumference direction of the body, and the groove portion has a with narrower near the center of the body than near the edge of the body.

In an embodiment, the width of the groove portion gradually increases toward the edge of the body from the center of the body.

In an embodiment, the brush unit further includes a plurality of contact protrusions protruding from a bottom of each groove portion.

In an embodiment, the contact protrusion protrudes from the bottom of the groove portion to flush with a bottom surface of the contact pad or less than thereof.

In an embodiment, the plurality of contact protrusions in each groove portion are grouped into a plurality of groups with a distance between adjacent groups being greater than a distance between adjacent contact protrusion in each group, at least one group of the contact protrusions is positioned near the center of the body, and at least one group of the contact protrusion is positioned near the edge of the body.

In an embodiment, a bottom end of the contact protrusion is convex.

In an embodiment, the contact pad is more ductile than the contact protrusion.

In an embodiment, a material of the contact pad includes a PVA (polyvinyl alcohol), and a material of the contact protrusion includes a nylon, a PP (polypropylene), or a silicon carbide (SiC).

In an embodiment, the body has a through-hole at a center thereof, and the contact pads protrude from the body to operationally contact a surface of the substrate supported on the substrate.

In an embodiment, the brush unit further includes a plurality of polishing pads in the groove portion operationally contacting a surface of the substrate supported on the supporting unit.

In an embodiment, the brush unit further includes a cleaning nozzle for discharging a cleaning liquid on a substrate supported on the support unit.

In an embodiment, the brush unit further includes: an arm for supporting the body and the cleaning nozzle; an arm driver for moving the arm; a holder for supporting a side of the body; a support rod penetrating the arm and connecting to the holder, and having an elastic member positioned therein; and a holder driver for rotating the holder.

In an embodiment, arm drivers move the body between a central region and an edge region of the substrate supported on the support unit.

The inventive concept provides a substrate treating apparatus. The substrate treating apparatus includes an index block; and a treating block adjacent to the index block, and wherein the index block includes: at least one load port on which a container for a substrate is placed; and an index frame in which an index robot for transferring the substrate between the container and the treating block is disposed, and wherein the treating block includes: a buffer unit configured to temporarily store the substrate; an inversion unit stacked over or under the buffer unit and configured to turn over the substrate; a treating chamber for treating the substrate; and a transfer chamber having a transfer robot for transferring the substrate between the buffer unit, the inversion unit, and the treating chamber, and wherein the treating chamber includes: a housing having a treating space; a support unit configured to support the substrate in the treating space; a liquid supply unit configured to supply a treating liquid to a substrate supported on the support unit; and a brush unit configured to clean the substrate supported on the support unit, and wherein the brush unit includes: a body having a circular-shaped cross-section and having a through-hole at a center thereof; a plurality of contact pads protruding from the body the plurality of contact pads being spaced apart from each other along a circumference direction of the body and defining a groove portion between adjacent contact pads for discharging foreign substances dropped from the substrate; at least one contact protrusion within the groove portion and protruding from a bottom of the grove; and a cleaning nozzle for discharging a cleaning liquid onto the substrate supported on the support unit.

In an embodiment, a width of the groove portion becomes gradually wider radially outward in the body.

In an embodiment, the groove portion has a fan shape when seen from above.

In an embodiment, the contact pad is more ductile than the contact protrusion.

The inventive concept provides a brush unit for removing foreign substances attached to a substrate by contacting the substrate. The brush unit includes a circular disc shaped body; and a plurality of contact pads protruding from the body along a circumferential direction of the body and defining a plurality of groove portions for discharging the foreign substances, each groove defined between adjacent contact pads; and at least one contact protrusion protruding in the groove portion from a bottom of the groove portion, and wherein the groove portion has a fan shape when seen from above.

In an embodiment, the contact protrusion protrudes from the bottom of the groove portion to flush with a bottom surface of the contact pad or less than thereof.

The inventive concept provides a substrate treating method using the apparatus. The substrate treating method includes supporting the substrate on the substrate supporting unit with a non-pattern surface of the substrate being exposed; contacting the contact pads to the non-pattern surface of the substrate; and supplying a cleaning liquid onto the non-pattern surface of the substrate so as to removing the foreign substances from the non-pattern surface of the substrate.

In an embodiment, the support unit rotates when the non-pattern surface contacts the contact pad.

In an embodiment, the body rotates when the contact pad contacts the non-pattern surface.

In an embodiment, the body rotates before the contact pad contacts the non-pattern surface, and the support unit rotates after the non-pattern surface contacts the contact pad.

In an embodiment, the body and the support unit rotate in different directions.

In an embodiment, the body and the support unit rotate in the same direction, and the number of rotations per unit time of the body and the number of rotations per unit time of the support unit are different from each other.

In an embodiment, when cleaning the non-pattern surface of the substrate, the body moves between a central region including a center of the substrate and an edge region of the substrate,

In an embodiment, at least one cycle movement of the body is performed, the one cycle movement of the body includes: moving the body downwardly to a central region including a center of the substrate so as to contact the contact pad to the non-pattern surface of the substrate, moving the body from the central region to an edge region of the substrate while keeping contacting the contact pad with the non-pattern surface, then moving the body upwardly so as to be spaced apart from the non-pattern surface of the substrate, then moving the body laterally so as to be above the central region for subsequent contacting the contact pad with the non-pattern surface of the substrate in the central region.

In an embodiment, at least one cycle movement of the body is performed, the one cycle movement of the body includes: moving the body downwardly to an edge region of the substrate so as to contact the contact pad to the non-pattern surface of the substrate, moving the body from the edge region to a central region of the substrate while keeping contacting the contact pad with the non-pattern surface of the substrate, then moving the body upwardly so as to be spaced apart from the non-pattern surface of the substrate, then moving the body laterally so as to be above the edge region for subsequent contacting the contact pad with the non-pattern surface of the substrate in the edge region.

In an embodiment, the substrate treating method further includes: turning over the substrate by using the inversion; supporting the substrate on the substrate supporting unit with a pattern surface of the substrate being exposed, the pattern surface being opposite the non-pattern surface; and cleaning the pattern surface by supplying a cleaning liquid onto the pattern surface, the liquid supplying unit supplying the cleaning liquid onto the pattern surface.

According to an embodiment of the inventive concept, a cleaning efficiency of a substrate may be increased.

According to an embodiment of the inventive concept, a contaminated chemical may be easily discharged to an outside of a pad, when cleaning a substrate using the pad.

According to an embodiment of the inventive concept, a damage of a substrate by a pad may be minimized, when cleaning the substrate using the pad.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a perspective view schematically illustrating a substrate treating apparatus according to an embodiment of the inventive concept.

FIG. 2 is a plan view schematically illustrating the substrate treating apparatus according to an embodiment of the inventive concept of FIG. 1.

FIG. 3 is a view taken along line I-I of FIG. 2.

FIG. 4 is a view taken along line II-II of FIG. 2.

FIG. 5 is a cross-sectional view schematically illustrating a structure of an inversion unit according to an embodiment.

FIG. 6 is a perspective view schematically illustrating a first transfer robot according to an embodiment.

FIG. 7 is a cross-sectional view schematically illustrating a first process chamber according to an embodiment.

FIG. 8 is a perspective view schematically illustrating a body, a contact pad, and a contact protrusion according to an embodiment.

FIG. 9 is a flowchart sequentially showing an embodiment of a process of transferring a substrate and treating the substrate using the substrate treating apparatus according to an embodiment of FIG. 1.

FIG. 10 to FIG. 13 sequentially illustrate an embodiment of an operation in which the substrate is inverted by an inversion unit.

FIG. 14 to FIG. 17 sequentially illustrate an embodiment of a first process treatment.

FIG. 18 is a partially enlarged view schematically illustrating a state in which a chemical is discharged from the body, the contact pad, and the contact protrusion.

FIG. 19 illustrates an embodiment of a second process treatment.

FIG. 20 and FIG. 21 schematically illustrates another embodiment of a brush unit.

FIG. 22 and FIG. 23 schematically illustrate another embodiment of the first process treatment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Example Embodiments of the disclosure are related with a substrate treating apparatus and method. The substrate to be treated may be any kind and type of substrate which could be used for manufacturing a semiconductor device, a semiconductor chip, etc. For example, the substrate to be treated may be a circular semiconductor wafer but may be other kind of substrate such as mask, other shape of substrate such as rectangular display panel. As an exemplary way, the treating apparatus and method will be described with respect to circular wafer.

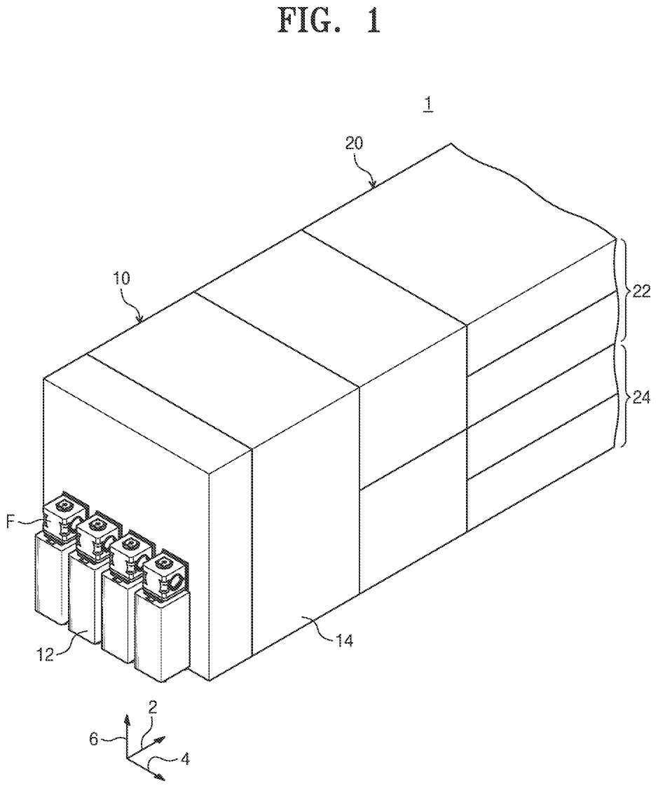

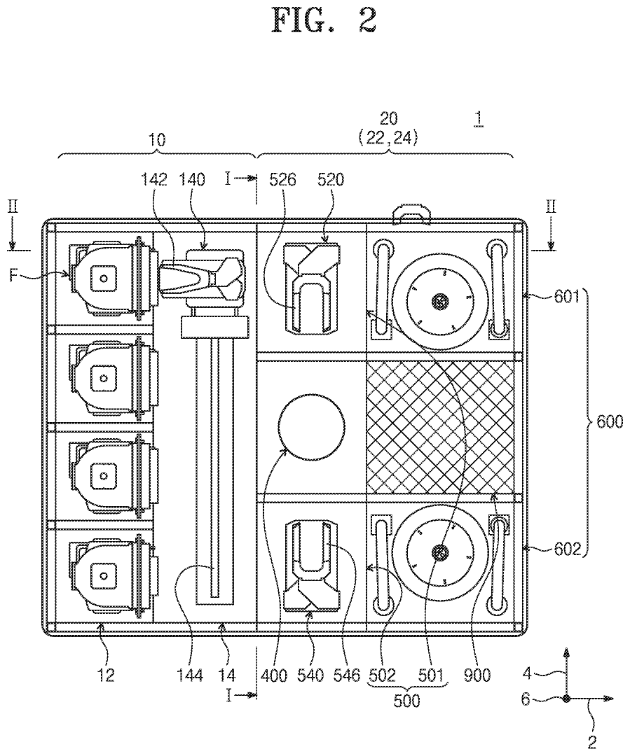

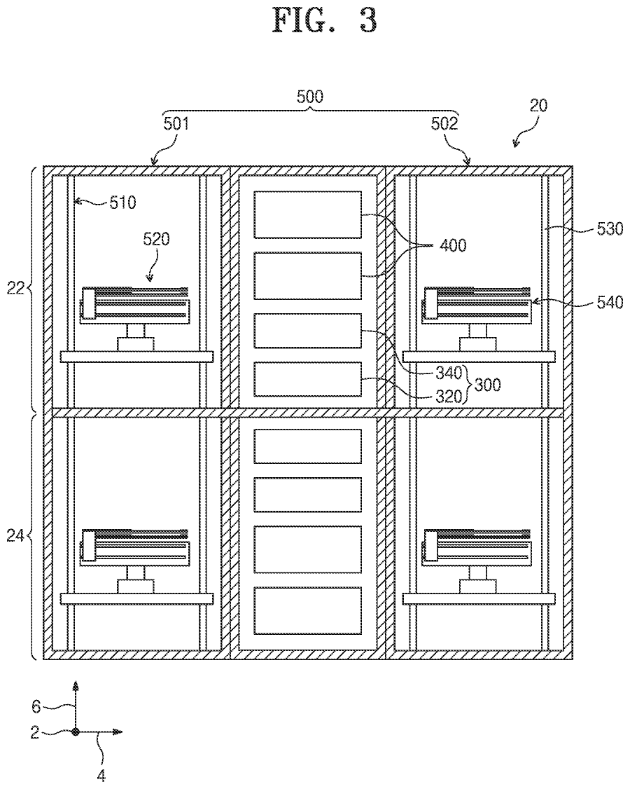

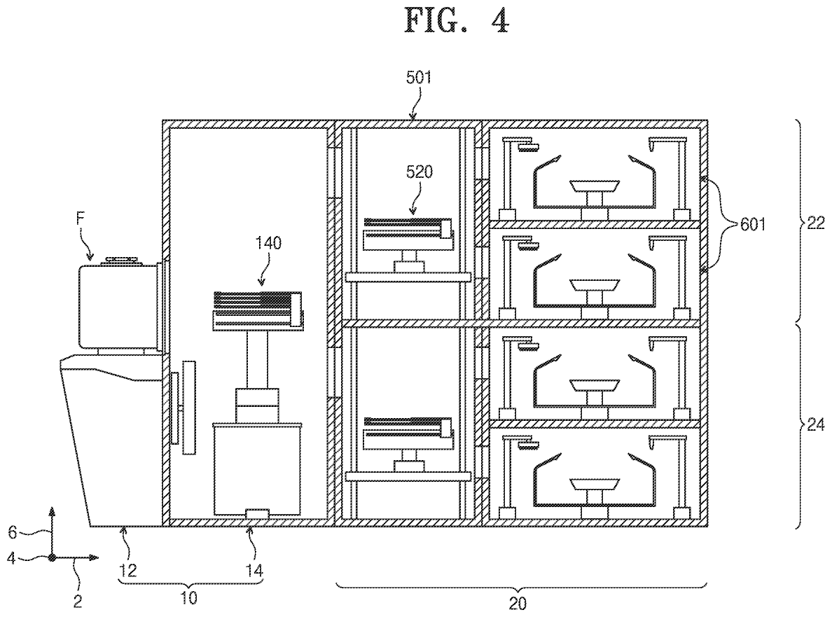

FIG. 1 is a perspective view schematically illustrating a substrate treating apparatus according to an embodiment of the inventive concept. FIG. 2 is a plan view schematically illustrating the substrate treating apparatus according to an embodiment of the inventive concept of FIG. 1. FIG. 3 is a view taken along line I-I of FIG. 2. FIG. 4 is a view taken along line II-II of FIG. 2.

Hereinafter, a substrate treating apparatus according to an embodiment of the inventive concept will be described in detail with reference to FIG. 1 to FIG. 4.

Referring to FIG. 1, the substrate treating apparatus 1 includes an index block 10 and a treating block 20. According to an embodiment, the index block 10 and the treating block may be disposed in a direction. Hereinafter, the direction in which the index block 10 and the treating block 20 are arranged will be referred to as a first direction 2, a direction perpendicular to the first direction 2 will be referred to as a second direction 4, and a direction perpendicular to a plane including both the first direction 2 and the second direction 4 will be referred to as a third direction 6.

The index block 10 transfers the substrate between the container F in which the substrate is stored and the treating block 20. For example, the index block 10 transfers the substrate on which a predetermined treatment has been completed in the treating block 20 to the container F. In addition, the index block 10 transfers the substrate on which a predetermined treatment is scheduled in the treating block 20 from the container F to the treating block 20. According to an embodiment, the index block 10 may have a lengthwise direction parallel to the second direction 4.

The treating block 20 may include a first treating block 22 and a second treating block 24. The first treating block 22 and the second treating block 24 are stacked each other. According to an embodiment, the first treating block 22 may be positioned above the second treating block 24. The first treating block 22 and the second treating block 24 have the same or similar structure and configuration.

Hereinafter, since the first treating block 22 and the second treating block 24 have the same or similar structure and configuration, in order to avoid repeated description on the same structure and configuration, the first treating block 22 will be mainly described. Accordingly, in FIG. 2 to FIG. 4, reference numerals are assigned only to components included in the first treating block 22, and reference numerals for components included in the second treating block 24 are omitted.

Referring to FIG. 1 and FIG. 2, the index block 10 may include a load port 12 and an index frame 14. A container F in which a substrate is stored is seated in the load port 12. The load port 12 and the treating block 20 are disposed opposite sides of the index frame 14. A plurality of load ports 12 may be provided, and a plurality of load ports 12 may be disposed along the second direction 4. The number of load ports 12 may increase or decrease according to a process efficiency of the treating block 20 and foot print conditions.

The container F may be a sealed container such as a front opening unified pod (FOUP). The container F may be placed in the load port 12 by a transfer means (not shown) such as an overhead transfer, an overhead conveyor, or an automatic guided vehicle or an operator.

The substrate according to an embodiment of the inventive concept has two opposite surfaces, main surface and back side surface. Various kinds and types of patterns are formed on the main surface during semiconductor manufacturing, so the main surface may be referred to as a pattern surface. On the other hand, no patterns are formed on the back side surface during semiconductor manufacturing, so the back side surface may be referred to as a non-pattern surface. The substrate according to an embodiment may be stored in the container F in a state in which the pattern surface faces upward.

Referring to FIG. 2, the index frame 14 has its lengthwise direction parallel to the second direction 4. The index frame 14 has a transfer space for transferring the substrate. The index robot 140 and the index rail 144 are disposed in the transfer space of the index frame 14. The index robot 140 transfers the substrate in the transfer space. Specifically, the index robot 140 transfers the substrate between the index block 10 and the treating block 20. The index robot 140 has an index hand 142.

The substrate is placed on the index hand 142. The index hand 142 may be forwardly and backwardly movable along the second direction 2, rotate about a vertical direction (e.g., the third direction 6) as an axis, and move up and down in an axial direction. A plurality of index hands 142 may be provided. Each of the plurality of index hands 142 may be disposed to be spaced apart in the vertical direction. The plurality of index hands 142 may forwardly and backwardly move independently of each other.

The index rail 144 may have its lengthwise direction parallel to the second direction 4. The index robot 140 is placed on the index rail 144, and the index robot 140 may move linearly along the lengthwise direction of the index rail 144. That is, the index robot 140 may forwardly and backwardly move along the index rail 144.

Referring to FIG. 2 to FIG. 3, the first treating block 22 may include a buffer unit 300, an inversion unit 400, a transfer chamber 500, and a treating chamber 600.

The buffer unit 300 has a buffer space. The buffer space functions as a space in which the substrate being transferred between the container F and the treating chamber 600 temporarily stays. The buffer unit 300 is disposed adjacent to the index frame 14. The buffer unit 300 and the index frame 14 are arranged in the first direction 92. In addition, the buffer unit 300 is disposed between the index frame 14 and a component storage space 900 to be described later.

The buffer unit 300 may have a main buffer 320 and a sub-buffer 340. Each of the main buffer 320 and the sub-buffer 340 has a buffer space. A slot (not shown) on which the substrate is seated is disposed in the buffer space of the main buffer 320 and the buffer space of the sub-buffer 340.

The substrate immediately after being taken out of the container F may temporarily remain in the buffer space of the main buffer 320. In addition, the substrate immediately before being taken into the container F may temporarily remain in the buffer space of the main buffer 320. According to an embodiment, the main buffer 320 may be a frame having a substantially rectangular parallelepiped shape. According to an embodiment, all side surfaces of the main buffer 320 may be opened. The buffer space of the main buffer 320 may function as a moving path of the index hand 142 described above, a first transfer hand 526 described later, or the second transfer hand 546 described later. Accordingly, the substrate transferred by the index hand 142, the first transfer hand 526, or the second transfer hand 546 may be seated in a slot (not shown) disposed in the main buffer 320.

The sub-buffer 340 is disposed to be stacked with the main buffer 320. According to an embodiment, the sub-buffer 340 may be positioned above the main buffer 320. The substrate immediately after being taken into the main buffer 320 may temporarily remain in the buffer space of the sub-buffer 340. In addition, the substrate immediately before being taken out to the main buffer 320 may temporarily remain in the buffer space of the sub-buffer 340. According to an embodiment, when transferring the substrate to any one of the main buffer 320, the inversion unit 400 to be described later, and the treating chamber 600, the substrate may temporarily remain in the sub-buffer 340 if it is difficult to transfer the substrate directly to the main buffer 320, the inversion unit 400, or the treating chamber 600 which are a transfer target point.

According to an embodiment, the sub-buffer 340 may have a substantially rectangular parallelepiped shape. Among the side surfaces of the sub-buffer 340, surfaces facing the first transfer chamber 501 and the second transfer chamber 502 to be described later may be opened. Accordingly, the buffer space of the sub-buffer 340 may function as a moving path of the first transfer hand 526 to be described later or the second transfer hand 546 to be described later. Accordingly, the substrate transferred by the first transfer hand 526 or the second transfer hand 546 may be seated in a slot (not shown) disposed in the sub-buffer 340.

Referring to FIG. 3, the inversion unit 400 is disposed to be stacked with the buffer unit 300 in the third direction 6. According to an embodiment, the inversion unit 400 may be positioned above the buffer unit 300. The inversion unit 400 turns over the substrate, thereby inverting positions of the pattern surface and the non-pattern surface of the substrate. According to an embodiment, the inversion unit 400 may be disposed above the sub-buffer 340. A plurality of inversion units 400 may be provided. According to an embodiment, two inversion units 400 may be provided in each of the first treating block 22 and the second treating block 24. The plurality of inversion units 400 may be disposed to be stacked on each other.

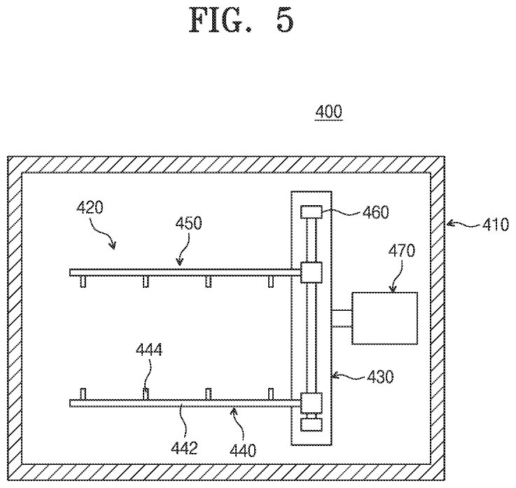

FIG. 5 is a cross-sectional view schematically illustrating a structure of the inversion unit according to an embodiment.

Referring to FIG. 5, the inversion unit 400 may include a housing 410 and an inversion member 420. The housing 410 may have a substantially rectangular parallelepiped shape. Among the side surfaces of the housing 410, an entrance (not shown) through which the substrate is taken in/out may be formed on a side surface facing the first transfer chamber 501 to be described later and a side surface facing the second transfer chamber 502 to be described later. The inversion member 420 is disposed inside the housing 410.

The inversion member 420 may include a rotary body 430, a first gripper 440, a second gripper 450, a linear driver 460, and a rotary driver 470.

The first gripper 440 and the second gripper 450 are mounted on the rotary body 430. The first gripper 440 is disposed to face the second gripper 450 in the vertical direction. The first gripper 440 and the second gripper 450 are vertically movably installed on the rotary body 430 such that a separation distance between them can be adjusted. The linear driver 460 changes positions of the first gripper 440 and the second gripper 450. In addition, the rotary driver 470 rotates the rotary body 430.

According to an embodiment, the first gripper 440 may include a support 442 and a grip pin 444. The support 442 is installed on the rotary body 430. The support 442 may generally have a disk shape. Alternatively, the support 442 may have a substantially ring shape. The grip pin 444 is coupled to the support 442. According to an embodiment, four grip pins 444 may be coupled to the support 442. The grip pins 444 support edge portions the substrate while the substrate is inverted. The first gripper 440 and the second gripper 450 may have a structure symmetrical to each other with respect to the substrate supported therebetween. Since the second gripper 450 has the same or similar structure as the first gripper 440, a description of the second gripper 450 will be omitted.

The liner driver 460 changes relative positions between the first gripper 440 and the second gripper 450 by vertically moving at least one of the first gripper 440 or the second gripper 450, thereby positioning the first and second gripper 440 and 450 in a grip position or a release position. The grip position may be defined as a position at which the first gripper 440 and the second gripper 450 are close to grip the substrate therebetween. The release position may be defined as a position at which the first gripper 440 and the second gripper 450 are spaced apart from each other enough to introduce the sub state in or take the substrate out from a space therebetween.

Referring back to FIG. 2 to FIG. 4, two transfer chambers 500 according to an embodiment may be provided in each of the first treating block 22 and the second treating block 24. Hereinafter, two transfer chambers 500 disposed in the first treating block 22 will be referred to as a first transfer chamber 501 and a second transfer chamber 502.

The first transfer chamber 501 is placed on one side of the inversion unit 400, and the second transfer chamber 502 is placed on the other side of the inversion unit 400 opposite the one side. When viewed from above, the first transfer chamber 501, the inversion unit 400, and the second transfer chamber 502 are sequentially arranged in a direction parallel to the second direction 4.

A transfer robot is disposed in the first transfer chamber 501 and the second transfer chamber 502, respectively. According to an embodiment, a first guide rail 510 and a first transfer robot 520 are disposed in the first transfer chamber 501. In addition, a second guide rail 530 and a second transfer robot 540 are disposed in the second transfer chamber 502. Since the first transfer chamber 501 and the second transfer chamber 502, the first guide rail 510, the second guide rail 530, and the first transfer robot 520 and the second transfer robot 540 have the same or similar structure, respectively, components included in the first transfer chamber 501 will be mainly described below.

The first guide rail 510 is disposed inside the first transfer chamber 501. The first guide rail 510 has a lengthwise direction parallel to the third direction 6. The first transfer robot 520 moves along the first guide rail 510. That is, the first guide rail 510 guides a movement of the first transfer robot 520 in the vertical direction.

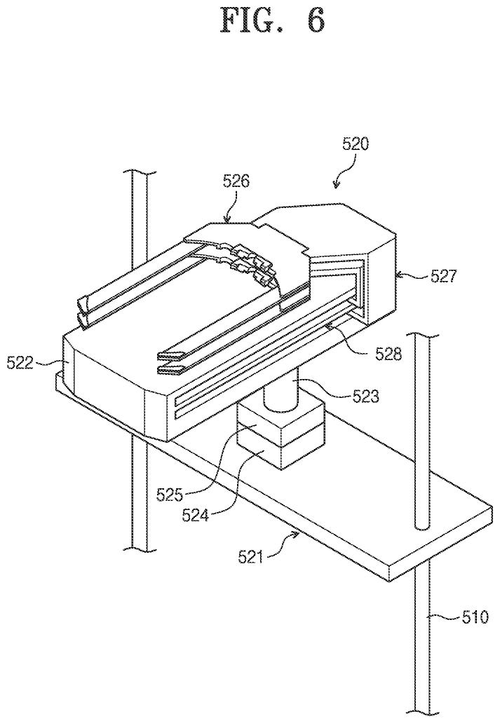

FIG. 6 is a perspective view schematically illustrating a first transfer robot according to an embodiment.

Referring to FIG. 6, the first transfer robot 520 may include a driving block 521, a base plate 522, and a first transfer hand 526.

The driving block 521 is movably installed on the first guide rail 510. The driving block 521 moves linearly along a lengthwise direction of the first guide rail 510. For example, the driving block 521 moves linearly parallel to the third direction 6. The base plate 522 is installed on the driving block 521 via a support shaft 523. The support shaft 523 is mounted on the driving block 521 so as to be rotatable about a central axis thereof by a rotary driver 524. According to an embodiment, the rotary driver 524 may be a motor. In addition, the support shaft 523 may be vertically moved by a vertical driver 525. For example, the vertical driver 525 may be a cylinder or a motor.

The first transfer hand 526 supports the substrate. A plurality of first transfer hands 526 may be provided. The plurality of first transfer hands 526 are disposed to face each other in the vertical direction. In addition, the plurality of first transfer hands 526 are disposed to be spaced apart from each other by a predetermined distance. According to an embodiment, there may be two first transfer hands 526. The plurality of first transfer hands 526 may move forward or backward independently of each other. Each of a plurality of first transfer hands 526 is installed on the base plate 522 via a bracket 527. The brackets 527 are coupled to respective guide hole 528 formed on a side of the base plate 522. That is, each bracket 527 is coupled to the base plate 522 through the respective guide hole 528, and the bracket 527 is moved by a driver which is not shown, thereby allowing the first transfer hand 526 coupled to the bracket 527 to forwardly and backwardly move.

Referring back to FIGS. 2 and 4, the treating chamber 600 performs a predetermined treatment on the substrate. According to an embodiment, the predetermined treatment may be a cleaning treatment in which foreign substances on the substrate are removed. The treating chamber 600 may include a first cleaning chamber 601 and a second cleaning chamber 602.

The first cleaning chamber 601 is disposed adjacent to the first transfer chamber 501. Based on the first transfer chamber 501, the index frame 14 is placed on one side of the first transfer chamber 501, and the first cleaning chamber 601 is placed on the other side of the first transfer chamber 501 opposite the one side. When viewed from above, the index frame 14, the first transfer chamber 501, and the first cleaning chamber 601 are sequentially arranged in a direction parallel to the first direction 2. According to an embodiment, a plurality of first cleaning chambers 601 may be provided. For example, two first cleaning chambers 601 may be provided in each of the first treating block 22 and the second treating block 24. The plurality of first cleaning chambers 601 are disposed to be stacked in the vertical direction. The plurality of first cleaning chambers 601 have the same or similar structure to each other, and may perform the same kind of treatment on the substrate.

The second cleaning chamber 602 is disposed adjacent to the second transfer chamber 502. Based on the second transfer chamber 502, the index frame 14 is placed on one side of the second transfer chamber 502, and the second cleaning chamber 602 is placed on the other side of the second transfer chamber 502 opposite the one side. When viewed from above, the index frame 14, the second transfer chamber 502, and the second cleaning chamber 602 are sequentially arranged along the second direction 4. According to an embodiment, a plurality of second cleaning chambers 602 may be provided. For example, two second cleaning chambers 602 may be provided in each of the first treating block 22 and the second treating block 24. The plurality of second cleaning chambers 602 are disposed to be stacked vertically. Each of the plurality of second cleaning chambers 602 has the same or similar structure, and may perform the same type of treatment on the substrate. In addition, the first cleaning chamber 601 and the second cleaning chamber 602 have the same structure and may perform the same kind of treatment on the substrate.

Due to the above arrangement, when viewed from the top, the first cleaning chamber 601 and the second cleaning chamber 602 are positioned in a direction parallel to the second direction 4. In addition, the first cleaning chamber 601 and the second cleaning chamber 602 are positioned to be spaced apart from each other.

A space between the first cleaning chamber 601 and the second cleaning chamber 602 may function as a component storage space 900. According to an embodiment, components may be stored in the component storage space 900. The components stored in the component storage space 900 may include electrical components, valve units, etc. In some embodiments, the component stored in the component storage space 900 may include various types of components used in a liquid supply system in addition to the electronic component or the valve unit.

Unlike the above-described example, a space between the first cleaning chamber 601 and the second cleaning chamber 602 may function as a passage through which an operator enters during a maintenance of the buffer unit 300, the inversion unit 400, the first cleaning chamber 601, or the second cleaning chamber 602. In this case, doors (not shown) accessible to workers may be installed on surfaces facing the buffer unit 300 and the inversion unit 400, surfaces facing the first cleaning chamber 601, and surfaces facing the second cleaning chamber 602.

The first cleaning chamber 601 and the second cleaning chamber 602 clean the substrate. Since the first cleaning chamber 601 and the second cleaning chamber 602 have the same or similar structures and perform the same kind of treatment on the substrate, the first cleaning chamber 601 will be mainly described hereinafter.

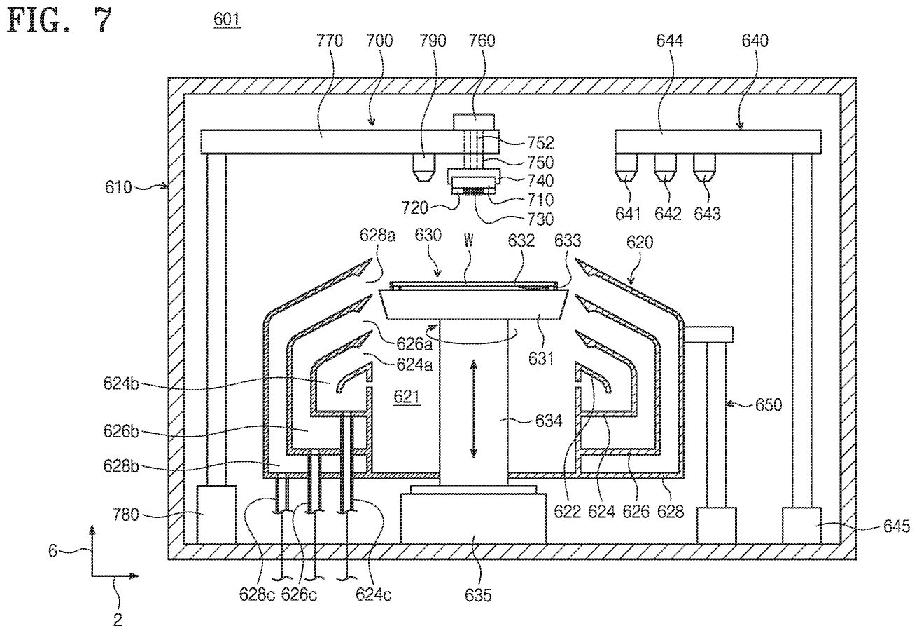

The first cleaning chamber 601 according to an embodiment performs a first process and a second process on a substrate. The first process may be a process of treating the substrate in a state in which the non-pattern surface of the substrate is upwardly disposed (i.e., non-pattern surface is exposed, facing upward). In addition, the second process may be a process of treating the substrate in a state in which the pattern surface of the substrate is upwardly disposed. According to an embodiment, in the first process, the non-pattern surface of the substrate may be cleaned using a brush unit 700 (see FIG. 7) to be described later. According to an embodiment, in the first process, the non-pattern surface may be cleaned using the brush unit 700 while supplying a cleaning solution to the non-pattern surface of the substrate. In addition, in the second process, the pattern surface of the substrate may be cleaned by supplying a treating liquid to the pattern surface of the substrate. In the second process, after cleaning the pattern surface of the substrate W by supplying the treating liquid to the pattern surface of the substrate, the treating liquid may be removed from the pattern surface of the substrate.

Specifically, according to an embodiment, the second process may include a removal process, a rinsing process, and a replacement process. According to an embodiment, the treating liquid may include a chemical, a rinsing liquid, or an organic solvent. For example, in the removal process, chemicals may be supplied to the pattern surface of the substrate to remove foreign substances such as particles, byproducts, etc., attached to the pattern surface of the substrate or a thin film. In addition, the rinsing process may remove chemicals supplied to the pattern surface of the substrate by supplying the rinsing liquid to the pattern surface of the substrate. For example, the rinsing liquid may include a water. In addition, in the replacement process, the organic solvent such as an isopropyl alcohol (IPA) is supplied to the pattern surface of the substrate to replace the rinsing liquid supplied to the pattern surface of the substrate with the organic solvent.

Unlike the above-described example, any one of the rinsing process and the replacement process may be omitted in the second process. In addition, the removal process may be performed multiple times using different types of chemicals. In addition, the removal process may be performed multiple times using the same type of chemical having different compositions.

Unlike the above-described example, the second process may be a process of supplying a polymer and a solvent to the pattern surface of the substrate and then volatilizing the solvent to form a solidified body on the pattern surface of the substrate and removing the solidified body from the pattern surface of the substrate.

FIG. 7 is a cross-sectional view schematically illustrating a first process chamber according to an embodiment.

Referring to FIG. 7, the first cleaning chamber 601 may include a housing 610, a treating container 620, a support unit 630, a liquid supply unit 640, a lifting/lowering unit 650, and a brush unit 700.

The housing 610 may have a substantially rectangular parallelepiped shape. An inlet (not shown) is formed on a sidewall of the housing 610. The inlet (not shown) functions as a passage through which the substrate W is taken in or taken out. The inlet (not shown) may be formed on a sidewall facing the first transfer chamber 501 (see FIG. 2) among sidewalls of the housing 610. The substrate W is taken into or taken out of the inner space of the housing 610 by the first transfer robot 520 (see FIG. 2). In the inner space of the housing 610, the treating container 620, the support unit 630, the liquid supply unit 640, the lifting/lowering unit 650, and the brush unit 700 are disposed.

The treating container 620 may be a bowl with an open top. The treating container 620 has a treating space 621 with an open top. The treating space 621 functions as a space in which the substrate W is treated. For example, the first cleaning process or the second cleaning process may be performed to the substrate W in the treating space 621. The support unit 630 supports the substrate W in the treating space 621. In addition, the support unit 630 rotates the substrate W in the treating space 621. The liquid supply unit 640 supplies the treating liquid to the substrate W supported by the support unit 630. The lifting/lowering unit 650 adjusts a relative height between the treating container 620 and the support unit 630.

According to an embodiment, the treating container 620 may have a guide wall 622 and a plurality of recollecting containers 624, 626, and 628. Each of the guide wall 622 and the recollecting containers 624, 626, and 628 have a ring shape surrounding the support unit 630. Each of the recollecting containers 624, 626, 628 have a recollecting space 624b, 626b, and 628b for separating and recollecting different liquids from the liquids used in the treatment of the substrate W. If the liquid treatment process is performed, a liquid scattered by the rotation of the substrate W is introduced into the above-described recollecting spaces 624b, 626b, and 628b through the inlets 624a, 626b, and 628b of each of the recollecting containers 624, 626, and 628.

According to an embodiment, the treating container 620 may include a first recollecting container 624, a second recollecting container 626, and a third recollecting container 628. The first recollecting container 624 is arranged to surround the support unit 630, the second recollecting container 626 is arranged to surround the first recollecting container 624, and the third recollecting container 628 is arranged to surround the second recollecting container 626. The first inlet 624a for introducing a liquid into the recollecting space 624b of the first recollecting container 624 is positioned below the second inlet 626a for introducing a liquid into the recollecting space 626b of the second recollecting container 626. In addition, the second inlet 626a is positioned below the third inlet 628a through which a liquid flows into the recollecting space 628b of the third recollecting container 628. At each of the recollecting containers 624, 626, and 628, liquid discharge pipes 624c, 626c, and 628c for discharging a liquid are coupled. The liquid discharged through the liquid discharge pipes 624c, 626c, and 628c may be reused using an external regeneration system (not shown).

The number of the above-described recollecting containers may be variously changed according to the number of liquids used and the number of liquids to be recollected or discarded. Although not shown, an exhaust line for exhausting a gas and a fume may be connected to a bottom surface of the treating container 620.

The support unit 630 may include a spin chuck 631 and a driving shaft 634. A top surface of the spin chuck 631 may have a substantially circular shape. In addition, the top surface of the spin chuck 631 may have a diameter larger than that of the substrate W. A support pin 632 for supporting a bottom surface of the substrate W may be disposed in a central portion of the spin chuck 631. A plurality of support pins 632 may be disposed on the spin chuck 631. The support pin 632 is disposed on a top part of the spin chuck 631. The support pin 632 is disposed such that a top end thereof upwardly protrudes from the top surface of the spin chuck 631. Accordingly, the substrate W is supported by a spin chuck 631 to be spaced apart from the top surface of the substrate W by a predetermined distance.

A chuck pin 633 is disposed at an edge of the spin chuck 631. The chuck pin 633 is disposed on a top part of the spin chuck 631. The chuck pin 633 is disposed such that a top end thereof protrudes from a top surface of the spin chuck 631. The chuck pin 633 supports a side of the substrate W so that if the substrate W rotates, the substrate W does not deviate laterally from a regular position on the support unit 630.

The driving shaft 634 is driven by the chuck driver 635 and is connected to the spin chuck 631. The driving shaft 634 may receive a power from the chuck driver 635 and rotate about its axis. Accordingly, the spin chuck 631 connected to the driving shaft 634 may also be rotated, and the substrate W supported by the spin chuck 631 may also be rotated. Also, according to an embodiment, the chuck driver 635 may move the spin chuck 631 in the vertical direction.

The liquid supply unit 640 may include a first nozzle 641, a second nozzle 642, and a third nozzle 643. The first nozzle 641 according to an embodiment supplies a chemical to the substrate W supported by the support unit 630. In addition, the second nozzle 642 supplies a water onto the substrate W supported by the support unit 630. The water according to an embodiment may be a pure water or a deionized water. In addition, the third nozzle 643 supplies an organic solvent to the substrate W supported by the support unit 630. The organic solvent according to an embodiment may be an isopropyl alcohol.

Each of the first nozzle 641, the second nozzle 642, and the third nozzle 643 is supported by an arm 644. The arm 644 is coupled to the driver 645. The driver 645 may swing or linearly move the arm 644. The nozzles 641, 642, and 643 may move between the standby position and the liquid supply position by the driver 645.

The standby position may be a position at which nozzles 641, 642, and 643 stand by when the treating liquid is not supplied to the substrate W. For example, in the standby position, the nozzles 641, 642, and 643 may be positioned outside the treating container 620 when viewed from above. The liquid supply position may be a position at which the nozzles 641, 642, and 643 supply a treating liquid to the substrate W. For example, in the liquid supply position, the nozzles 641, 642, and 643 may be positioned inside the treating container 620 when viewed from above.

Unlike the above-described example, the first nozzle 641, the second nozzle 642, and the third nozzle 643 may be respectively connected to different arms, and each arm may be independently connected to different drivers. In addition, the liquid supply unit 640 may further include one or more nozzles in addition to the first nozzle 641, the second nozzle 642, and the third nozzle 643. An added nozzle may supply another type of treating liquid to the substrate W.

The lifting/lowering unit 650 changes the position of the treating container 620. For example, the lifting/lowering unit 650 moves the treating container 620 in the vertical direction (e.g., the third direction 6). A relative height between the treating container 620 and the substrate W supported by the support unit 630 is changed by the vertical movement of the treating container 620. Accordingly, the recollecting containers 624, 626, and 628 may separate and recollect the liquid according to the type of the liquid supplied to the substrate W. Unlike the above-described example, the position of the treating container 620 is fixed, and the support unit 630 moves in the vertical direction by the chuck driver 635, thereby changing the relative height between the treating container 620 and the substrate W.

The brush unit 700 cleans the substrate W supported by the support unit 630. The brush unit 700 removes foreign substances attached to the substrate W supported by the support unit 630 from the substrate W. According to an embodiment, the brush unit 700 may remove foreign substances attached to the non-pattern surface of the substrate W.

The brush unit 700 may include a body 710, a contact pad 720, a contact protrusion 730, a holder 740, a support rod 750, a holder driver 760, and a cleaning nozzle 790.

The body 710 may be supported by the holder 740. According to an embodiment, the holder 740 may support a side portion of the body 710. The holder 740 may include an elastic material. According to an embodiment, the material of the holder 740 may include a PEEK.

The support rod 750 generally has a rod shape. The support rod 750 may penetrate the arm 770. The support rod 750 may penetrate the arm 770 and be connected to the holder driver 760 disposed on a top surface of the arm 770. According to an embodiment, one end of the support rod 750 is connected to the top end of the holder 740, and the other end of the support rod 750 is connected to the holder driver 760. Accordingly, the body 710 may be coupled to the arm 770 by the support rod 750 at an end of the arm 770.

The holder driver 760 may rotate the holder 740 about the support rod 750 as an axis, and may also rotate the body 710 supported by the holder 740. In addition, the holder driver 760 may move the holder 740 in the vertical direction through the support rod 750. Accordingly, the body 710 supported by the holder 740 may also move in the vertical direction. For example, the holder driver 760 may be a motor.

An elastic member 752 may be disposed within the support rod 750. The elastic member 752 may extend from a top end of the support rod 750 to a bottom end of the support rod 750. According to an embodiment, the elastic member 752 may be a spring. If the contact pad 720 to be described later comes into contact with the non-pattern surface of the substrate W and scrubs the substrate W, the elastic member 752 may alleviate a pressure applied to the non-pattern surface of the substrate W to minimize a damage to the substrate W.

The arm 770 supports the body 710 and the cleaning nozzle 790 to be described later. The arm 770 is coupled to the arm driver 780. The arm driver 780 may move the entire arm 770 including the body 710 in the vertical direction. In addition, the arm driver 780 may swing the entire arm 770 including the body 710. The arm driver 780 may include a plurality of motors. One of the plurality of motors may be a linear motor, and the other may be a rotating motor.

The position of the body 710 may be changed by the holder driver 760 and/or the arm driver 780. According to an embodiment, the body 710 may be moved between a standby position and a process position by the holder driver 760 and/or the arm driver 780. The process position may be a position at which the contact pad 720 and/or the contact protrusion 730 to be described later may contact the substrate W, and the standby position may be a position at which the body 710 stands by if the brush unit 700 does not treat the substrate W. For example, the body 710 in the process position may be positioned inside the treating container 620 when viewed from above. In addition, the body 710 in the standby position may be positioned outside the treating container 620 when viewed from above.

The cleaning nozzle 790 may be installed in the arm 770. A bottom end of the cleaning nozzle 790 may be positioned above a bottom end of the contact pad 720 described below. The cleaning nozzle 790 discharges a cleaning liquid to the substrate. The cleaning nozzle 790 discharges the cleaning liquid to the non-pattern surface of the substrate W supported by the support unit 630. The cleaning liquid according to an embodiment may be a pure water or a deionized water. Unlike FIG. 7, the cleaning nozzle 790 may be installed closer to a front end of the arm 770 than the body 710.

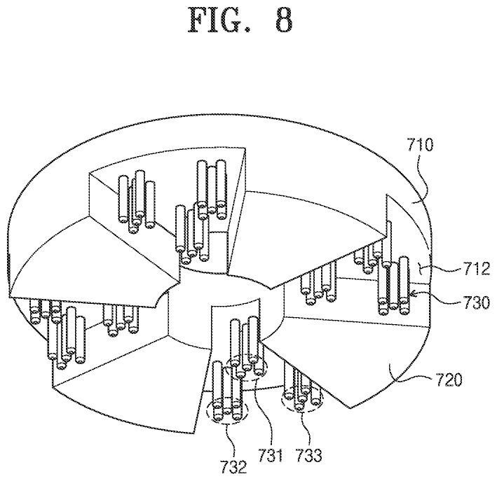

FIG. 8 is a perspective view schematically illustrating a body, a contact pad, and a contact protrusion according to an embodiment. Hereinafter, the body, the contact pad, and the contact protrusion according to an embodiment of the inventive concept will be described in detail with reference to FIG. 8.

The body 710 may generally have a disk shape. A central region of the body 710 may be penetrated. That is, according to an embodiment, the body 710 may be a circular ring shape having a predetermined thickness and may have planar top and bottom surfaces.

The contact pad 720 will contact the substrate W during cleaning process to drop off the foreign substances attached to the substrate W. For example, during cleaning process, the contact pad 720 may contact the non-pattern surface of the substrate W and scrub the non-pattern surface of the substrate W, thereby removing foreign substances attached to the non-pattern surface of the substrate W. The contact pad 720 is formed on the body 710. The contact pad 720 is formed to downwardly protrude from the bottom surface of the body 710. According to an embodiment, the body 710 and the contact pad 720 may be integrally formed.

The contact pad 720 may be formed to protrude from the bottom surface of the body 710 by a predetermined distance. An inner curvature of the contact pad 720 may correspond to a curvature of a central region of the body 710. In addition, an outer curvature of the contact pad 720 may correspond to a curvature of an edge region of the body 710. Namely, contact pad 720 may extend radially through the entire diameter direction. According to an embodiment, the contact pad 720 may have a generally fan-shaped shape when viewed from above. For example, a width of the contact pad 720 may gradually increase from the central region of the body 710 to the edge region of the body 710.

A material of the contact pad 720 according to an embodiment may include a material having relatively a greater ductility than the contact protrusion 730 to be described later. Specifically, the material of the contact pad 720 may include a material having a relatively small Young's modulus than the contact protrusion 730. For example, the material of the contact pad 720 may include a polyvinyl alcohol (PVA).

The contact pad 720 may be provided in plural. Namely a plurality of contact pads 720 may be arranged in a spaced-apart manner along a circumferential the body 710 on the bottom surface thereof. A space between adjacent contact pads 720 may be defined as a groove portion 712. When viewed from above, the contact pads 720 and the groove portion 712 are alternately arranged along the circumferential direction of the body to define the shape of the bottom surface of the body 710. If the contact pad 720 contacts the non-pattern surface of the substrate W, the groove portion 712 functions as a space into which foreign substances which are separated from the non-pattern surface of the substrate W are discharged. A detailed mechanism for this will be described later.

According to an embodiment, the width of the groove portion 712 in the central region of the body 710 may be different from the width of the groove portion 712 in the edge region of the body 710. According to an embodiment, the width of the groove portion 712 in the central region of the body 710 may be smaller than the width of the groove portion 712 in the edge region of the body 710. According to an embodiment, the width of the groove portion 712 may gradually increase from the central region to the edge region of the body 710. That is, the groove portion 712 according to an embodiment may have a generally fan-shaped shape when viewed from above.

The contact protrusion 730 in the groove portion 712 scrapes off foreign substances attached to the substrate W. The contact protrusions 730 may remove foreign substances which are not removed by the contact pad 720 from the non-pattern surface of the substrate W. A material of the contact protrusion 730 according to an embodiment may include a material having a relatively stronger rigidity than the contact pad 720. Specifically, the material of the contact protrusion 730 may include a material having a relatively larger Young's modulus than the contact pad 720. For example, the material of the contact protrusion 730 may include a nylon, a polypropylene (PP), or a silicon carbide (SiC).

The contact protrusion 730 is installed on the body 710. The contact protrusion 730 is disposed in the groove portion 712. The contact protrusion 730 may extend vertically from a bottom of the groove portion 712. According to an embodiment, the contact protrusion 730 may have a substantially rod shape. In some embodiments, the contact protrusion 730 may have a plurality of bristle. In addition, the bottom end of the contact protrusion 730 which contacts the surface of the substrate during cleaning process may be formed to be rounded, i.e., convex.

The bottom end of the contact protrusion 730 downwardly protrudes from the bottom surface of the body 710 (i.e., bottom surface of the groove portion 712) by a predetermined distance. In addition, the bottom end of the contact protrusion 730 may flush with the bottom end of the contact pad 720. For example, the bottom end of the contact protrusion 730 may be positioned at the same height as the bottom end of the contact pad 720. In this case, the contact protrusion 720 may be in contact with the non-pattern surface of the substrate W during cleaning process. Accordingly, the contact protrusion 720 may remove foreign substances attached to the non-pattern surface of the substrate W from the non-pattern surface of the substrate W.

More preferably, the bottom end of the contact protrusion 730 may be positioned at a height which does not protrude from the bottom end of the contact pad 720. That is, the bottom end of the contact protrusion 730 may be slightly lower than the bottom end of the contact pad 720. In this case, a height difference between the bottom end of the contact protrusion 730 and the bottom end of the contact pad 720 may be a fine value of several micrometers to several millimeters. In this case, even though the contact protrusion 720 does not directly contact the substrate W during cleaning process, the contact protrusion 270 may contact foreign substances protruding from the non-pattern surface of the substrate W, thereby removing foreign substances from the non-pattern surface of the substrate W.

Since the contact protrusion 730 is made of a material with a relatively stronger rigidity than the contact pad 720, if the bottom end of the contact protrusion 730 protrudes more downwardly than the bottom end of the contact pad 720, during cleaning process, the contact protrusion 730 may contact the substrate W earlier than the contact pad 720. However, according to some embodiments of the disclosure, the bottom end of the contact protrusion 730 is lower than or flushed with the bottom end of the contact pad 720, it is possible to minimize damage to the substrate W which may be caused by contact between the contact protrusion 730 and the substrate W prior to contact between the contact pad 720 and the substrate W.

Hereinafter, an exemplary embodiment of disclosure will be described for the case that the bottom end of the contact protrusion 730 is positioned at the same height as the bottom end of the contact pad 720.

A plurality of contact protrusions 730 may be provided. The plurality of contact protrusions 730 may be grouped into a plurality of groups. For example, five contact protrusions 730 may form one group. The contact protrusions 730 included in each group may be spaced apart from each other by a predetermined distance. The distance between adjacent two contact protrusions 730 in each group may be smaller than the distance between adjacent two groups. In the example shown in FIG. 8, the protrusions 730 have first, second and third groups 731, 732 and 733 with each group having five contact protrusions.

The first group 731 may be positioned in the groove portion 712 adjacent the central region of the body 710 The second group 732 and the third group 733 may be positioned in the groove portion 712 adjacent the edge region of the body 710. For example, the second group 732 and the third group 733 may be positioned far away from the center of the body 710 by the same distance. Namely, the second and third groups 732 and 733 in each groove portion 712 may be arranged along the circumferential direction of the body 710.

The first groups 731 may be arranged in respective groove portion 712 to define a circle having a first diameter which is smaller than a diameter of through-hole of the body 710. The second groups 732 and the third groups 733 may be arranged respective groove portion 712 to define a circle having a second diameter which is greater than the first diameter of the circle defined by the first groups 731 but smaller than a diameter of the body 710.

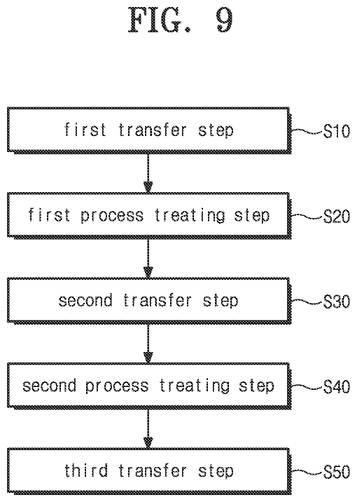

FIG. 9 is a flowchart sequentially showing an embodiment of a process of transferring the substrate and treating the substrate using the substrate treating apparatus according to an embodiment of FIG. 1.

Hereinafter, a substrate treating method using the substrate treating apparatus according to an embodiment of FIG. 1 will be described in detail with reference to FIG. 9. The substrate treating method described below may be performed by controlling the substrate treating apparatus by a controller which is not shown. For example, the controller may control components of the substrate treating apparatus according to an embodiment of FIG. 1. Hereinafter, the substrate treating method according to an embodiment of the inventive concept will be described by citing the reference numerals shown in FIG. 1 to FIG. 8.

The controller may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The substrate treating method according to an embodiment of the inventive concept may include a first transfer step S10, a first process treating step S20, a second transfer step S30, a second process treating step S40, and a third transfer step S50. According to an embodiment, the first transfer step S10, the first process treating step S20, the second transfer step S30, the second process treating step S40, and the third transfer step S50 may be sequentially performed.

In the first transfer step S10, the substrate W is transferred from the container F to the first cleaning chamber 601 or/and the second cleaning chamber 602. Hereinafter, for convenience of description, in the first transfer step S10, the substrate W is transferred from the container F to the first cleaning chamber 601 as an example.

The index robot 120 takes the substrate W out of the container F placed in the load port 12 and brings it into the main buffer 320. As mentioned above, since the substrate W is placed with the pattern surface facing upward in the container F, the substrate W is stored in the main buffer 320 with the pattern surface facing upward. The first transfer robot 520 takes out the substrate W from the main buffer 320 and takes the substrate W into the inversion unit 400. According to an embodiment, if all the inversion units 400 are full of substrates W and cannot receive any further substrate, the first transfer robot 520 may take the substrate W into the sub-buffer 340 from the main buffer 320. Thereafter, when any one of the inversion units 400 is empty, the first transfer robot 520 may take out the substrate W from the sub-buffer 340 and transfer the substrate W to the inversion unit 400.

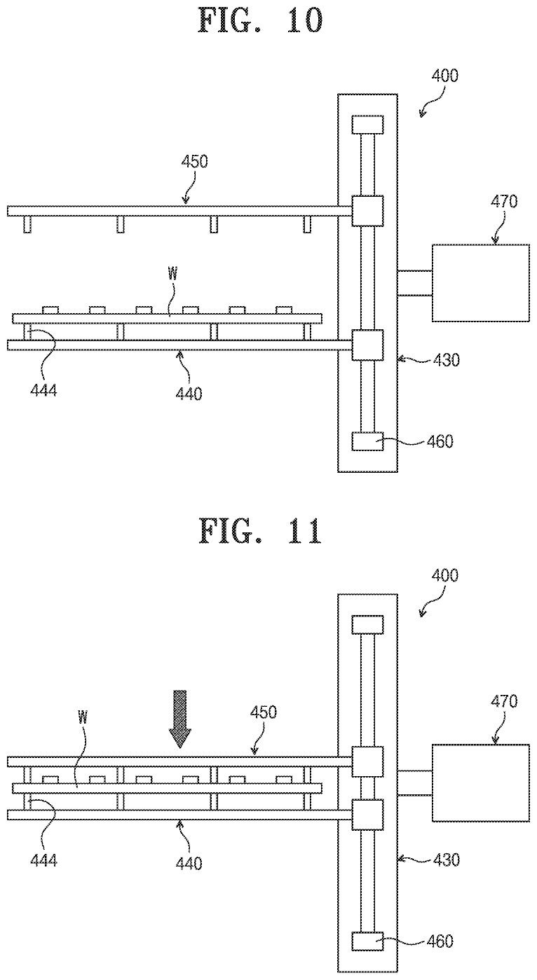

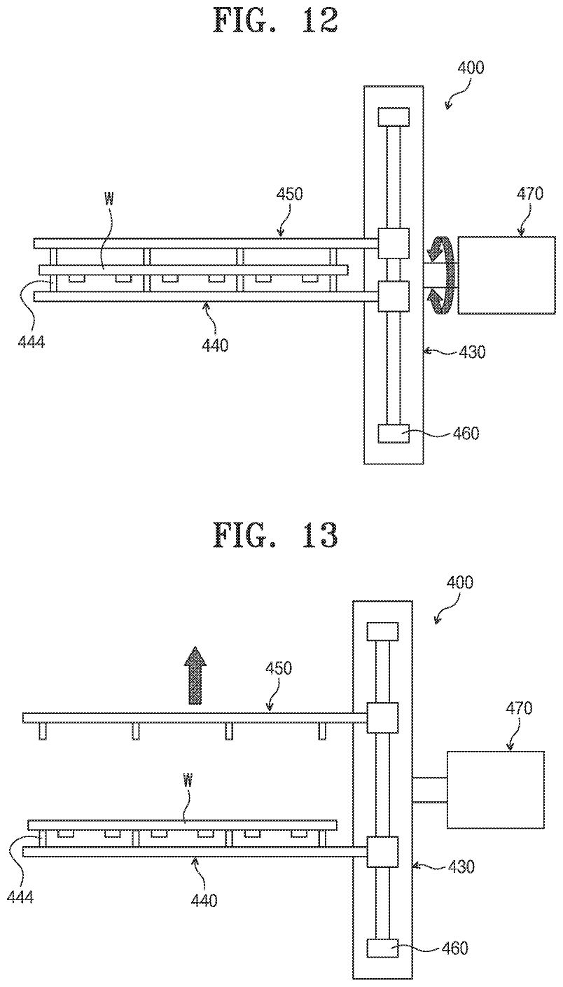

FIG. 10 to FIG. 13 sequentially illustrate an embodiment of an operation in which the substrate is turned over by the inversion unit.

Referring to FIG. 10 to FIG. 13, positions of the pattern surface and the non-pattern surface of the substrate W are inverted in the inversion unit 400. According to an embodiment, with the first gripper 440 and the second gripper 450 disposed at a release position, the substrate W is transferred between the first gripper 440 and the second gripper 450. Thereafter, the first gripper 440 and the second gripper 450 move from the release position to a grip position. Accordingly, the substrate W is gripped by the first gripper 440 and the second gripper 450. In a state in which the substrate W is gripped, a rotary driver 470 rotates a rotary body 430. The substrate W is turned over according to rotation of the rotary body 430. That is, the substrate W is turned over and thus the non-pattern surface faces upward. Thereafter, the first gripper 440 and the second gripper 450 move from the grip position to the release position.

The first transfer robot 520 takes out the substrate W from the inversion unit 400 and takes the substrate W into the first cleaning chamber 601. In this case, the substrate W is taken into the first cleaning chamber 601 with the non-pattern surface facing upward and supported by the support unit 630.

In the first process treating step S20, a first process is performed on the non-pattern surface of the substrate W. According to an embodiment, in the first process, the non-pattern surface of the substrate W is cleaned using the brush unit 700. According to an embodiment, in the first process, a cleaning solution may be discharged to the non-pattern surface of the substrate W, and at the same time, the non-pattern surface of the substrate W may be cleaned using the brush unit 700.

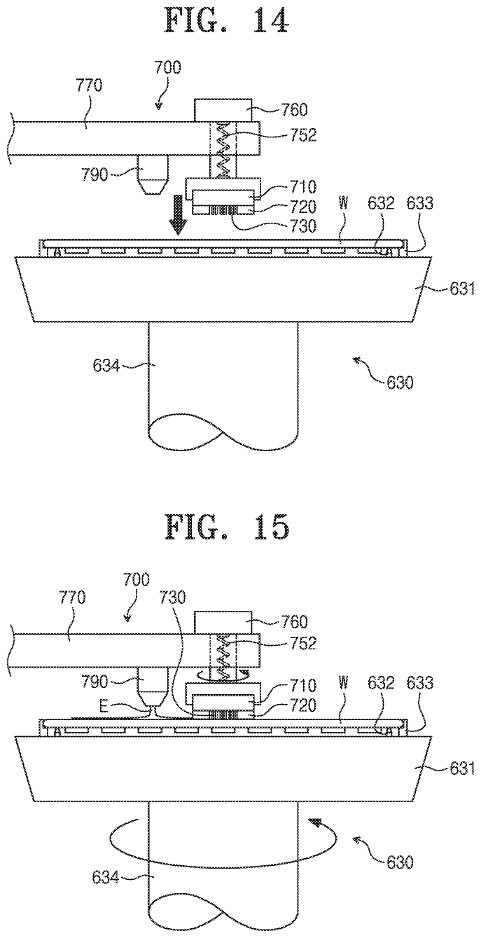

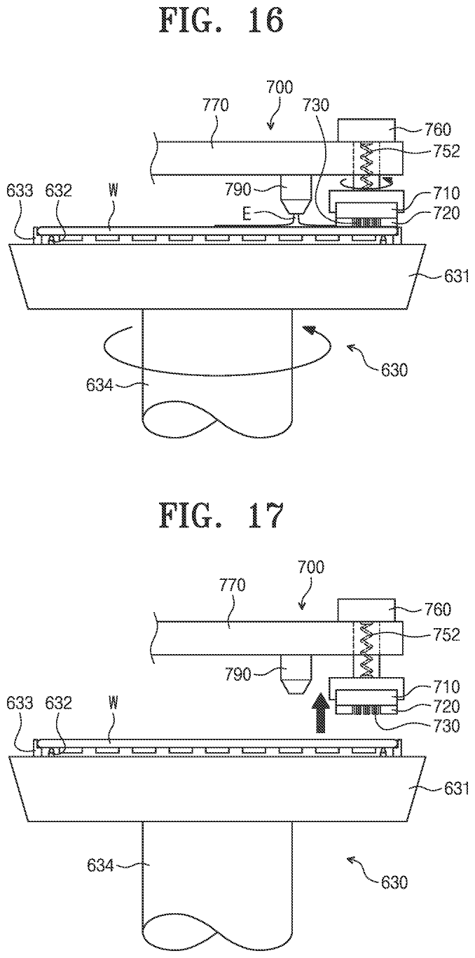

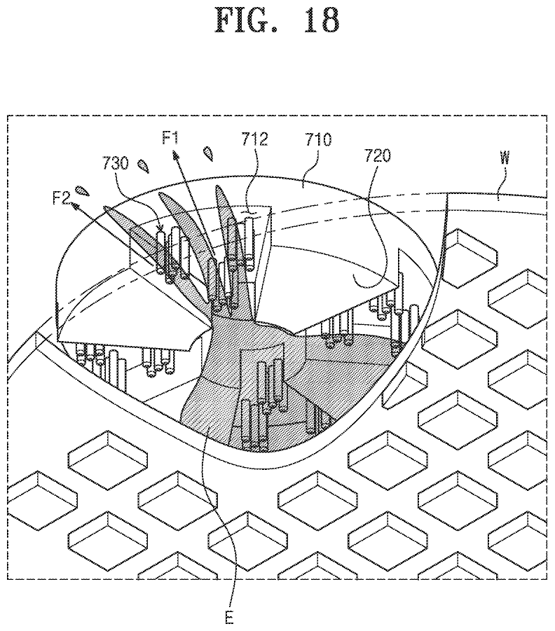

FIG. 14 to FIG. 17 sequentially illustrate an embodiment of the first process treatment.

The substrate W with the pattern surface facing downward is supported by the support unit 630. In this case, the support pin 632 and the chuck pin 633 do not interfere with the pattern surface of the substrate W, respectively. Once the substrate W is supported by the support unit 630, the body 710 moves from the standby position to the process position. For example, the body 710 may move inside the substrate W when viewed from above. The body 710 moves over the central region of the substrate W. The body 710 positioned over the center of the substrate W moves downward, and accordingly, the contact pad 720 and/or the contact protrusion 730 may contact the non-pattern surface in the center region of the substrate W.

In some embodiments, the body 710 may rotate before the contact pad 720 and/or the contact protrusion 730 comes into contact with the non-pattern surface of the substrate W. That is, while the body 710 rotating, the contact pad 720 and/or the contact protrusion 730 may contact the non-pattern surface of the substrate W. In some embodiments, spin chuck 631 may rotate after the contact pad 720 and/or the contact protrusion 730 comes into contact with the non-pattern surface of the substrate W. However, the inventive concept is not limited to this, and the spin chuck 631 may rotate before or at the same time the contact pad 720 and/or the contact protrusion 730 contacts the non-pattern surface of the substrate W.

According to an embodiment, a rotation direction of the body 710 and a rotation direction of the spin chuck 631 may be the same. In this case, the number of rotations per unit time of the body 710 and the number of rotations per unit time of the spin chuck 631 may be different from each other. For example, the number of rotations per unit time of the body 710 may be greater than the number of rotations per unit time of the spin chuck 631.

In addition, when the contact pad 720 and/or the contact protrusion 730 and the substrate W contact each other, the elastic member 752 may be pressurized. Accordingly, it is possible to minimize an occurrence of damage to the substrate W while the body 710 moves downward to contact the substrate W.

In addition, while the contact pad 720 and/or the contact protrusion 730 and the substrate W are in contact with each other, the cleaning nozzle 790 discharges the cleaning liquid E toward the non-pattern surface of the substrate W. Since the spin chuck 631 is rotating, the cleaning liquid E discharged from the cleaning nozzle 790 may flow to an entire region of the substrate W. Unlike the above example, the cleaning nozzle 790 may discharge the cleaning liquid E toward the non-pattern surface of the substrate W before the contact pad 720 and/or the contact protrusion 730 and the substrate W come into contact with each other. In addition, the cleaning liquid E may be continuously discharged during the contact pad 720 and/or the contact protrusion 730 and the substrate W are in contact with each other.

The body 710 moves from a central region of the substrate W to an edge region of the substrate W. While the body 710 moves from the central region of the substrate W to the edge region of the substrate W, the body 710 continuously rotates. In addition, while the body 710 moves from the central region of the substrate W to the edge region of the substrate W, the contact pad 720 and/or the contact protrusion 730 may continuously contact the non-pattern surface of the substrate W. While the spin chuck 631 rotates, the body 710 moves from the central region to the edge region of the substrate W, so that the entire region of the non-pattern surface of the substrate W contacts the contact pad 720 and/or the contact protrusion 730. While the contact pad 720 and/or the contact protrusion 730 continuously contacts the non-pattern surface of the substrate W, foreign substances attached to the non-pattern surface of the substrate W are removed from the non-pattern surface of the substrate W.

Once the body 710 is moved to the edge region, the body 710 upwardly moves and is spaced apart from the non-pattern surface of the substrate W by a predetermined distance. The body 710 moves again from the position over the edge region of the substrate W to the position over the central region of the substrate W. Once the body 710 is positioned over the central region of the substrate W, the body 710 moves downward again to contact the non-pattern surface of the substrate W with the contact pad 720 and/or the contact protrusion 730. The above-described cleaning mechanism (movement of the body 710) may be performed at least once.

A large amount of foreign substances may be attached to the non-pattern surface of the substrate. Such foreign substances may bounce back to the pattern surface of the substrate in a subsequent process, causing process defects. In addition, if foreign substances attached to the non-pattern surface of the substrate are not removed, the substrate may be tilted by foreign substances attached to a part supporting the substrate when treating the substrate while supporting the substrate in the subsequent process.

In general, when cleaning the substrate using a conventional pad, foreign substances attached to the substrate are removed by contact between the pad and the substrate. In this case, a contaminated cleaning liquid mixed with foreign substances removed from the substrate may not be discharged from between the conventional pad and the substrate and is trapped between the pad and the substrate. The contaminated cleaning liquid which has not been discharged remains on a surface of the conventional pad, and foreign substances mixed with the cleaning liquid may be attached to the substrate again when the conventional pad cleans other regions of the substrate.

FIG. 18 is a partially enlarged view schematically illustrating a state in which a chemical is discharged from the body, the contact pad, and the contact protrusion.

Referring to FIG. 18, the cleaning liquid E discharged and remaining on the non-pattern surface of the substrate is discharged to the groove portion 712 by the contact pad 720. Due to the shape of the contact pad 720, the width of the groove portion 712 gradually increases from the central region of the body 710 to the edge region. Due to the structural characteristics of the groove portion 712, a force F1 of a capillary tube of the cleaning liquid E in the groove portion 712 increases toward the edge region of the body 710. Since a capillary force F1 in the groove portion 712 increases from the central region to the edge region of the body 710, the cleaning liquid E in the groove portion 712 is induced to be discharged from the central region toward the edge region. Accordingly, the cleaning liquid within the groove portion 712 and foreign substances (not shown) mixed with the cleaning liquid E are discharged to the outside of the body 710 and removed from the substrate.

The contact protrusion 730 according to an embodiment of the inventive concept has a rounded bottom end thereof, e.g., convex. Accordingly, the capillary force F2 is generated by an interface between the rounded (convex) bottom end of the contact protrusion 730 and the non-pattern surface of the substrate W, contributing to a discharge of the cleaning liquid E in the groove portion 712. In addition, a plurality of contact protrusions 730 are closely disposed to form a group, it is possible to further increase the capillary force F2 by contact protrusions 730 in a group.

In addition, since the material of the contact pad 720 according to an embodiment of the inventive concept includes a flexible material (e.g., PVA), it is possible to minimize a damage to the non-pattern surface of the substrate W when it comes into contact with the substrate W. That is, it is prevented that the contact pad 720 according to an embodiment of the inventive concept deforms the non-pattern surface of the substrate W.

In general, when cleaning the substrate using the conventional pad, it is not possible to apply a large force for contacting the conventional pad to the substrate in order to avoid a damage to the substrate by a large force. When foreign substances attached to the surface of the substrate comprise a material which is difficult to be removed from the substrate, the foreign substances are not easily removed using the conventional pad. However, according to some embodiments, since the material of the contact protrusion 730 includes a highly rigid material, foreign substances which are not easily removed by the contact pad 720 may be easily removed from the non-pattern surface of the substrate W.

In addition, since the body 710 rotates during a contact with the non-pattern surface of the substrate W, an angular velocity in the central region including the center of the body 710 is relatively smaller than an angular velocity in the edge region of the body 710. Accordingly, the central region of the body 710 according to an embodiment has a thorough-hole in the center, so that the cleaning liquid E staying in the central region of the body 710 may be easily discharged to the edge region of the body 710.

Referring back to FIG. 9, the second transfer step S30 is performed after the first process treating step S20 is completed. If the first process treating step S20 is completed, the first transfer robot 520 takes out the substrate W from the first cleaning chamber 601 and transfers it to an empty inversion unit 400. In the inversion unit 400, positions of the pattern surface and the non-pattern surface of the substrate W are inverted. For example, in the inversion unit 400, the substrate W may be turned over such that the pattern surface faces upward. The first transfer robot 520 transfers the substrate W turned over to the first cleaning chamber 601. However, the inventive concept is not limited thereto, and the first transfer robot 520 may transfers the substrate W to one of the first cleaning chamber 601, the second cleaning chamber 602, and the sub-buffer 340 depending on the process situation in the treating chamber 600.

The substrate W taken into the first cleaning chamber 601 is supported by the support unit 630 while the pattern surface faces upward. Once the substrate W is supported by the support unit 630, a second process treating step S40 is performed.

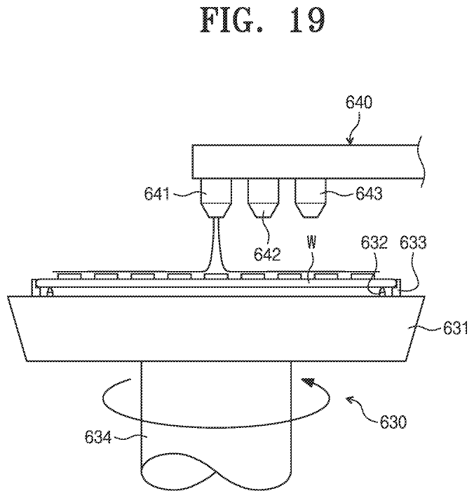

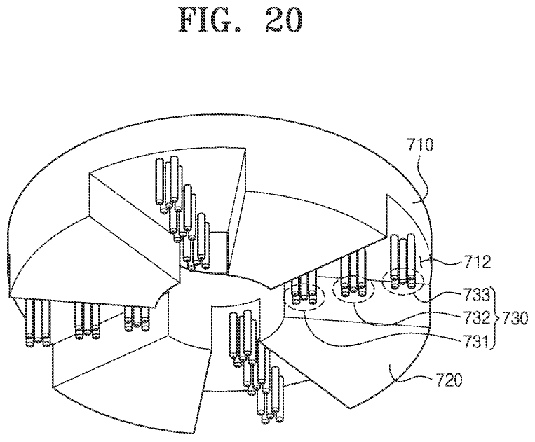

FIG. 19 illustrates an embodiment of a second process treatment.

Referring to FIG. 19, the liquid supply unit 640 supplies the treating liquid toward the pattern surface of the substrate W. For example, the liquid supply unit 640 may sequentially supply a chemical, a rinsing liquid, and an organic solvent to the pattern surface of the substrate W. However, the inventive concept is not limited thereto, and only a part of the chemical, the rinsing liquid, and the organic solvent may be supplied to the pattern surface of the substrate W, and a supply sequence of the chemical, the rinsing liquid, and the organic solvent may be changed.

Referring back to FIG. 9, after the second process treating step S40 is completed, the first transfer robot 520 takes out the substrate W from the first cleaning chamber 601 and transfers it to the main buffer 320. In this case, the substrate W maintains a state in which the pattern surface faces upward. If there is no empty space in the main buffer 320, the first transfer robot 520 takes the substrate W into the sub-buffer 340. Thereafter, if an empty space is created in the main buffer 320, the first transfer robot 520 takes out the substrate W from the sub-buffer 340 and brings it into the main buffer 320. Thereafter, the index robot 120 takes out the substrate W from the main buffer 320 and stores the substrate W into the container F placed on the load port 12.

According to an embodiment of the inventive concept, the first process treating step S20 of cleaning the non-pattern surface of the substrate W may be performed first, and then the second treating step S40 of cleaning the pattern surface of the substrate W may be performed. In the process of performing the first process treating step S20, foreign substances may be attached to the pattern surface of the substrate W. In this case, by performing the second process treating step S40 after the first process treating step S20, foreign substances may be removed from the pattern surface of the substrate W in the second process treating step S40.

Unlike the aforementioned example, the body 710 may rotate after the contact pad 720 and/or the contact protrusion 730 contacts the non-pattern surface formed on the substrate W or at the same time.

Unlike the above example, the cleaning liquid may be supplied to the non-pattern surface of the substrate W before the contact pad 720 and the contact protrusion 730 come into contact with the non-pattern surface of the substrate W, and the cleaning liquid may not be supplied to the substrate W while the contact pad 720 and the contact protrusion 730 are contacting with the non-pattern surface of the substrate W.

In addition, after the contact pad 720 and the contact protrusion 730 contact with the non-pattern surface of the substrate W and remove foreign substances from the non-pattern surface of the substrate W, the treating liquid may be supplied to the non-pattern surface of the substrate W. In addition, after supplying the treating liquid, the substrate W may be rotated at a high speed to be dried.

In addition, before the contact pad 720 and the contact protrusion 730 contact with the non-pattern surface of the substrate W and remove foreign substances from the non-pattern surface of the substrate W, the treating liquid may be supplied to the non-pattern surface of the substrate W. Thereafter, while discharging the cleaning liquid to the non-pattern surface of the substrate W, the contact pad 720 and the contact protrusion 730 contact the non-pattern surface of the substrate W, and the rinsing liquid may be supplied to the non-pattern surface of the substrate W.

In addition, unlike the above-described example, after the second process treating step S40 is performed first, the first process treating step S20 may be performed.

In addition, unlike the above-described example, the brush unit 700 may not include the cleaning nozzle 790. In this case, when performing the first process treating step S20, the liquid supply unit 640 may supply a deionized water to the non-pattern surface of the substrate W. When the liquid supply unit 640 supplies the deionized water to the non-pattern surface of the substrate W, an arm 644 of the liquid supply unit 640 and an arm 770 of the brush unit 700 may operate so as not to interfere with each other.

In addition, unlike the above example, the brush unit 700 can contact the pattern surface of the substrate W and remove impurities attached to the pattern surface of the substrate W from the pattern surface of the substrate W.

In addition, unlike the above-described examples, the first process treating step S20 of cleaning only the non-pattern surface of the substrate W may be performed in one of the first cleaning chamber 601 and second cleaning chamber 602, and the second process treating step S40 of cleaning only the pattern surface of the substrate W may be performed in the other of the first cleaning chamber 601 and the second cleaning chamber 602.

In addition, unlike the above-described example, one treating block 20 may be provided. Selectively, three or more treating blocks 20 may be provided. Also, unlike the above-described example, the buffer unit 300 may include only the main buffer 320.

Hereinafter, the brush unit according to another embodiment of the inventive concept will be described. The brush unit according to an embodiment described below has a structure which is mostly the same as or similar to that of the brush unit 700 described with reference to FIG. 7 and FIG. 8, except for a case in which it is additionally described. Therefore, hereinafter, a description of the overlapping configuration will be omitted.

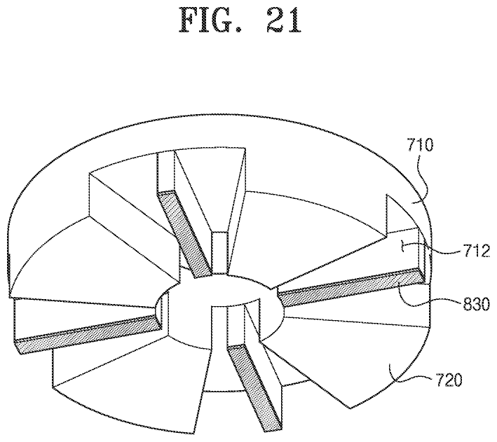

FIG. 20 and FIG. 21 schematically illustrate another embodiment of the brush unit.

Referring to FIG. 20, the first group 731, the second group 732, and the third group 733 in the groove portion 712 may be sequentially arranged along the radial direction, i.e., along a direction from the central region toward the edge region of the body 710. For example, the first group 731 is positioned closer to the central region of the body 710 than the second group 732 and the third group 733. In addition, the second group 732 is positioned closer to the central region of the body 710 than the third group 733. The third group 733 is positioned closer to the edge region of the body 710 than the first group 731 and the second group 732. However, the inventive concept is not limited to the above-described example, and groups composed of a plurality of protrusions 730 may be disposed in various regions within the groove portion 712.

Referring to FIG. 21, the brush unit 700 according to an embodiment of the inventive concept may include a body 710, a contact pad 720, a holder 740, a support rod 750, a holder driver 760, a cleaning nozzle 790 and a polishing pad 830. Hereinafter, the polishing pad 830 will be mainly described.

The polishing pad 830 according to an embodiment may be disposed in the respective groove portion 712. In some embodiments, a plurality of polishing pads may be disposed in each groove portion 717. In some embodiment, at least one groove portion 712 may include a plurality of polishing pads. A bottom end of the polishing pad 830 may be positioned at the same height as the bottom end of the contact pad 720. According to an embodiment, the polishing pad 830 may be integrally formed with the body 710.

According to an embodiment of the inventive concept described above, when the contact pad 720 contacts the non-pattern surface of the substrate W, the polishing pad 830 also contacts the non-pattern surface of the substrate W. Fine and uniform pores may exist on the bottom surface of the polishing pad 830. Selectively, fine grooves may be uniformly formed on the bottom surface of the polishing pad 830. Accordingly, when the polishing pad 830 is in contact with the non-pattern surface of the substrate W, it is possible to minimize a generation of scratches on the non-pattern surface of the substrate W. In addition, foreign substances attached to the non-pattern surface of the substrate W and not easily removed by the contact pad 720 can be easily removed by the polishing pad 830.

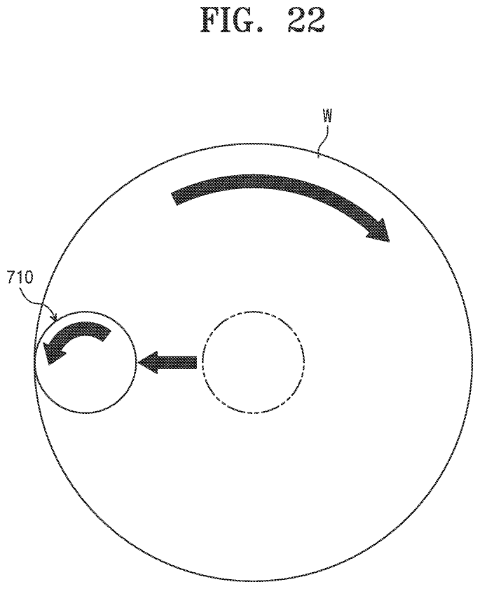

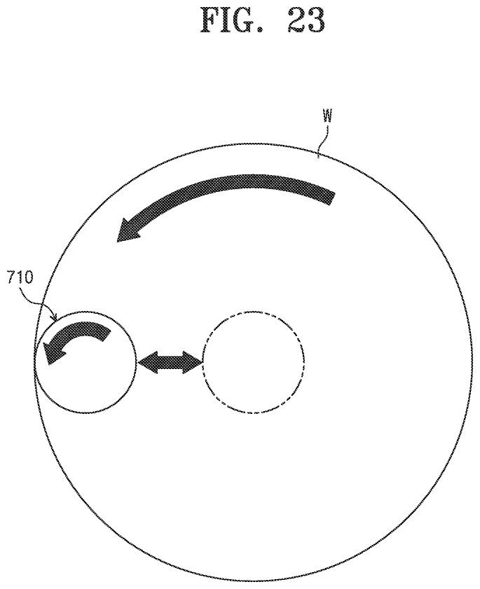

FIG. 22 and FIG. 23 schematically illustrate another embodiment of the first treatment.

Referring to FIG. 22, the substrate W and the body 710 may rotate in the first process treating step, respectively. According to an embodiment, the substrate W and the body 710 may rotate in different directions. For example, the substrate W may rotate in a counterclockwise direction, and the body 710 may rotate in a clockwise direction. Selectively, the substrate W may rotate clockwise, and the body 710 may rotate counterclockwise.

According to an embodiment of the inventive concept, as the substrate W and the body 710 rotate in opposite directions, foreign substances attached to the non-pattern surfaces of the substrate W can be removed more easily. That is, according to an embodiment of the inventive concept, if a contamination of the non-pattern surface of the substrate W is relatively serious, foreign substances attached to the non-pattern surface of the substrate W can be removed more efficiently by setting rotation directions of the substrate W and the body 710 in opposite directions.

Referring to FIG. 23, in the first process treating step, the body 710 may reciprocate between the central region of the substrate W and the edge region of the substrate W. The body 710 may move back and forth multiple times between the central region of the substrate W and the edge region of the substrate W while cleaning the non-pattern surface of the substrate W.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a housing having a treating space;
a support unit configured to support a substrate in the treating space; and
a brush unit configured to clean the substrate supported on the support unit, and
wherein the brush unit includes:
a body having a circular-shaped cross-section; and
a plurality of contact pads protruding from the body and defining a plurality of groove portions for discharging foreign substances dropped from a substrate, each groove portion defined between adjacent contact pads, and
wherein
a width of the groove portion near a center of the body is different from a width of the groove portion near an edge of the body.

2. The substrate treating apparatus of claim 1, wherein the plurality of contact pads are disposed along a circumference direction of the body, and
the groove portion has a with narrower near the center of the body than near the edge of the body.

3. The substrate treating apparatus of claim 2, wherein the width of the groove portion gradually increases toward the edge of the body from the center of the body.

4. The substrate treating apparatus of claim 1, wherein the brush unit further includes a plurality of contact protrusions protruding from a bottom of each groove portion.

5. The substrate treating apparatus of claim 4, wherein the contact protrusion protrudes from the bottom of the groove portion to flush with a bottom surface of the contact pad or less than thereof.

6. The substrate treating apparatus of claim 4, wherein the plurality of contact protrusions in each groove portion are grouped into a plurality of groups with a distance between adjacent groups being greater than a distance between adjacent contact protrusion in each group, at least one group of the contact protrusions is positioned near the center of the body, and at least one group of the contact protrusion is positioned near the edge of the body.

7. The substrate treating apparatus of claim 4, wherein a bottom end of the contact protrusion is convex.

8. The substrate treating apparatus of claim 4, wherein the contact pad is more ductile than the contact protrusion.

9. The substrate treating apparatus of claim 8, wherein a material of the contact pad comprises a PVA (polyvinyl alcohol), and
a material of the contact protrusion comprises a nylon, a PP (polypropylene), or a silicon carbide (SiC).

10. The substrate treating apparatus of claim 1, wherein the body has a through-hole at a center thereof, and
the contact pads protrude from the body to operationally contact a surface of the substrate supported on the substrate.

11. The substrate treating apparatus of claim 1, wherein the brush unit further comprises a plurality of polishing pads in the groove portion operationally contacting a surface of the substrate supported on the supporting unit.

12. The substrate treating apparatus of claim 1, wherein the brush unit further comprises a cleaning nozzle for discharging a cleaning liquid on a substrate supported on the support unit.

13. The substrate treating apparatus of claim 12, wherein the brush unit further comprises:
an arm for supporting the body and the cleaning nozzle;
an arm driver for moving the arm;
a holder for supporting a side of the body;
a support rod penetrating the arm and connecting to the holder, and having an elastic member positioned therein; and
a holder driver for rotating the holder.

14. The substrate treating apparatus of claim 13, wherein arm drivers moves the body between a central region and an edge region of the substrate supported on the support unit.

15. A substrate treating apparatus comprising:
an index block; and
a treating block adjacent to the index block, and
wherein the index block includes:
at least one load port on which a container for a substrate is placed; and
an index frame in which an index robot for transferring the substrate between the container and the treating block is disposed, and
wherein the treating block includes:
a buffer unit configured to temporarily store the substrate;
an inversion unit stacked over or under the buffer unit and configured to turn over the substrate;
a treating chamber for treating the substrate; and
a transfer chamber having a transfer robot for transferring the substrate between the buffer unit, the inversion unit, and the treating chamber, and
wherein the treating chamber includes:
a housing having a treating space;
a support unit configured to support the substrate in the treating space;
a liquid supply unit configured to supply a treating liquid to a substrate supported on the support unit; and
a brush unit configured to clean the substrate supported on the support unit, and
wherein the brush unit includes:
a body having a circular-shaped cross-section and having a through-hole at a center thereof;
a plurality of contact pads protruding from the body the plurality of contact pads being spaced apart from each other along a circumference direction of the body and defining a groove portion between adjacent contact pads for discharging foreign substances dropped from the substrate;
at least one contact protrusion within the groove portion and protruding from a bottom of the grove; and
a cleaning nozzle for discharging a cleaning liquid onto the substrate supported on the support unit.

16. The substrate treating apparatus of claim 15, wherein a width of the groove portion becomes gradually wider radially outward in the body.

17. The substrate treating apparatus of claim 15, wherein the groove portion has a fan shape when seen from above.

18. The substrate treating apparatus of claim 15, wherein the contact pad is more ductile than the contact protrusion.

19. A brush unit for removing foreign substances attached to a substrate by contacting the substrate comprising:
a circular disc shaped body; and
a plurality of contact pads protruding from the body along a circumferential direction of the body and defining a plurality of groove portions for discharging the foreign substances, each groove defined between adjacent contact pads; and
at least one contact protrusion protruding in the groove portion from a bottom of the groove portion, and
wherein the groove portion has a fan shape when seen from above.

20. The brush unit of claim 19, wherein the contact protrusion protrudes from the bottom of the groove portion to flush with a bottom surface of the contact pad or less than thereof.

21-30. (canceled)
